(19) United States
(12) Patent Application Publication
(10) Pub. No.: US 2023/0062030 A1
(43) Pub. Date: Mar. 2, 2023

(54) SEMICONDUCTOR DEVICE WITH SEAL RING

(71) Applicant: Yangtze Memory Technologies Co., Ltd., Wuhan (CN)

(72) Inventor: SiPing HU, Wuhan (CN)

(73) Assignee: Yangtze Memory Technologies Co., Ltd., Wuhan (CN)

(21) Appl. No.: 17/451,026

(22) Filed: Oct. 15, 2021

Related U.S. Application Data
(63) Continuation of application No. PCT/CN2021/115794, filed on Aug. 31, 2021.

(51) Int. Cl. H01L 23/04; H01L 27/11526; H01L 27/11524; H01L 27/1157; H01L 27/11573; H01L 23/58

(52) U.S. Cl. CPC H01L 23/04; H01L 23/585; H01L 27/1157; H01L 27/11524; H01L 27/11526; H01L 27/11573

(57) ABSTRACT

Aspects of the disclosure provide a semiconductor device. In some examples, the semiconductor device includes a seal ring structure surrounding the region. The seal ring structure includes a first wall structure that extends through the silicon layer, and a first length of the first wall structure along a side periphery of the first die is longer than a pitch of contact structures.

### RELATED APPLICATION

This application is a bypass continuation of International Application No. PCT/CN2021/115794 filed on Aug. 31, 2021. The entire disclosure of the prior application is hereby incorporated by reference in its entirety.

### TECHNICAL FIELD

The present application describes embodiments generally related to semiconductor devices and fabrication processes for semiconductor devices.

### BACKGROUND

Integrated circuits (IC) can be fabricated in multiples on a wafer. The wafer is sawed into individual IC chips once the fabrication is complete. Generally, uppermost surfaces of the IC chips can be protected by a passivation layer. However, the passivation layer cannot cover the side periphery of each IC chip. To protect integrated circuits from exposure of undesirable moisture and ionic contaminants coming in from the side periphery of each IC chip, a seal ring (also referred to as guard ring) can be formed of metal material around the side periphery of each IC chip as part of the fabrication of the IC chip prior to sawing the wafer. The seal ring can provide structural reinforcement and stop undesirable moisture and mobile ionic contaminants from entering active circuitry regions of the IC chip and affecting operational reliability.

### SUMMARY

Aspects of the disclosure provide a semiconductor device. In some examples, the semiconductor device includes a first die. The first die incudes a silicon layer, and first circuit structures formed in a region of the silicon layer. Further, in an example, the first die includes a first wall structure configured to form a first loop that encloses the region, and the first wall structure extends through the silicon layer. In another example, the first die includes first wall structures configured to surround the region, and the first wall structures extend through the silicon layer.

In some examples, the semiconductor device includes a seal ring structure surrounding the region. The seal ring structure includes a first wall structure that extends through the silicon layer, and a first length of the first wall structure along a side periphery of the first die is longer than a pitch of contact structures.

In an example, the first wall structure and the contact structures are formed of a same metal material.

In an example, the first wall structure through the silicon layer is configured to be a closed loop that encloses the region. In another example, the seal ring structure includes multiple first wall structures that extend through the silicon layer. The multiple first wall structures form a loop along the side periphery of the first die, and the loop encloses the region and includes gaps between adjacent first wall structures.

In some examples, the seal ring structure includes the first wall structures that extend through the silicon layer and contact structures that extend through the silicon layer. In some examples, the seal ring structure includes first wall structures that form a first loop enclosing the region and second wall structures that forms a second loop enclosing the first loop and the region. The first wall structures and the second wall structures are staggered. In an example, a gap between two of the secodn wall structures being blocked by one of the first wall structures.

In some examples, the seal ring structure includes a third wall structure that extends through an insulating layer.

In some examples, the first circuit structures are formed on a face side of the first die, and the semiconductor device includes a second die that is bonded face-to-face with the first die, the second die includes second circuit structures formed on a face side of the second die. In some examples, the first circuit structures include an NAND memory array, and the second circuit structures include periphery circuitry for the NAND memory array.

In an example, the seal ring structure includes a pad layer disposed at a back side of the first die, the first wall structure is conductively connected with the pad layer.

Aspects of the disclosure provide a method for semiconductor device fabrication. In some examples, the method includes forming first circuit structures in a region of a first die, and forming a seal ring structure surrounding the region. The seal ring structure includes a first wall structure that extends through a silicon layer of the first die, a first length of the first wall structure along a side periphery of the first die is longer than a pitch of first contact structures.

In some examples, to form the first wall structures and the first contact structures, the method includes forming a trench and holes in the silicon layer; and filling a metal material in the trench and the holes to form the first wall structure in the trench and the first contact structures in the holes.

In some examples, the method includes bonding the first die with a second die face to face, and forming the first wall structure by processing from a back side of the first die. In an example, to form the first wall structure by processing from the back side of the first die, the method includes thinning a silicon substrate of the first die from the back side of the first die, and forming the first wall structure in the thinned silicon substrate.

In another example, to form the first wall structure by processing from the back side of the first die, the method includes removing a silicon substrate from the back side of the first die, depositing the silicon layer at the back side of the first die, and forming the first wall structure in the silicon layer.

Aspects of the disclosure also provide a layout for forming a through silicon metal wall.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C shows cross-sectional views of a semiconductor device 100 according to some embodiments of the disclosure.

FIGS. 2A-2D show the cross sectional views of some other semiconductor device according to some embodiments of the disclosure.

FIG. 2E shows a cross section view of a related semiconductor device.

FIGS. 3A-3B shows cross-sectional views of another semiconductor device according to some embodiments of the disclosure.

FIG. 4 shows a flow chart outlining a process for forming a semiconductor device according to some embodiments of the disclosure.

FIGS. 5-7 show cross-sectional views of a semiconductor device during a fabrication process in accordance with some embodiments.

FIG. 8 shows layout designs in some examples.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Aspects of the disclosure provide techniques to form a seal ring structure including a portion that is formed in a silicon layer from a back side of a wafer, and the portion of the seal ring structure in the silicon layer can be formed with improved reinforcement strength and improved protection for moisture and mobile ionic contaminants. The seal ring structure can provide structural reinforcement for further processing at the back side of the wafer and can prevent entering of undesirable moisture and mobile ionic contaminants into active circuitry regions of integrated circuit (IC) chips from side periphery.

According to some aspects of the disclosure, a semiconductor device (e.g., an IC chip) can include multiple IC dies bonded together. In some examples, a semiconductor device includes two dies (e.g., a first die and a second die) bonded face-to-face. Pad structures for interfacing circuitry in the semiconductor device with external circuitry can be formed on a back side of one of the two dies.

In some examples, the multiple dies can be bonded before the formation of the pad structures. For example, a first wafer including multiples of the first die and a second wafer including multiples of the second die can be bonded face-to-face. Then, the bonded wafers are further processed, for example, to form pad structures on the back side of the wafer for interfacing the semiconductor device with external circuitry, to be sawed into IC chips, and the like. According to an aspect of the disclosure, the seal ring structure formed according to the present disclosure can provide better structural reinforcement for further processing from the back side of the wafer.

In some examples, the processing from the back of the wafer may cause defects in one or more layers at the back side. According to another aspect of the disclosure, the seal ring structures formed according to the present disclosure can prevent entering of undesirable moisture and mobile ionic contaminants from the defects in the one or more layers at the back side.

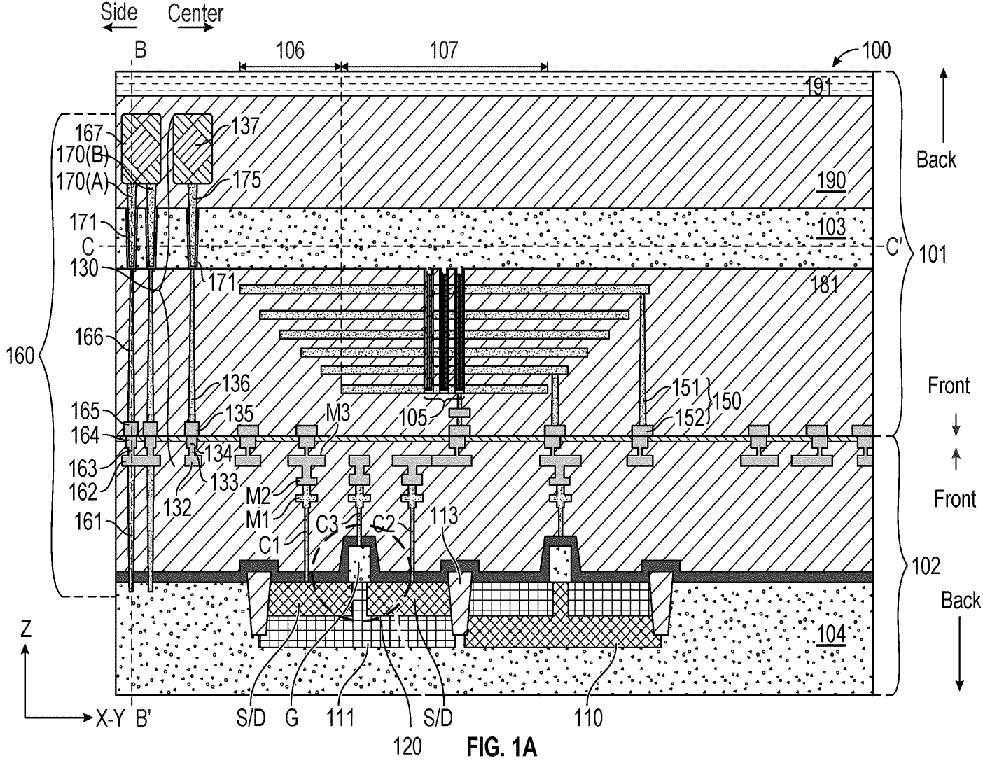

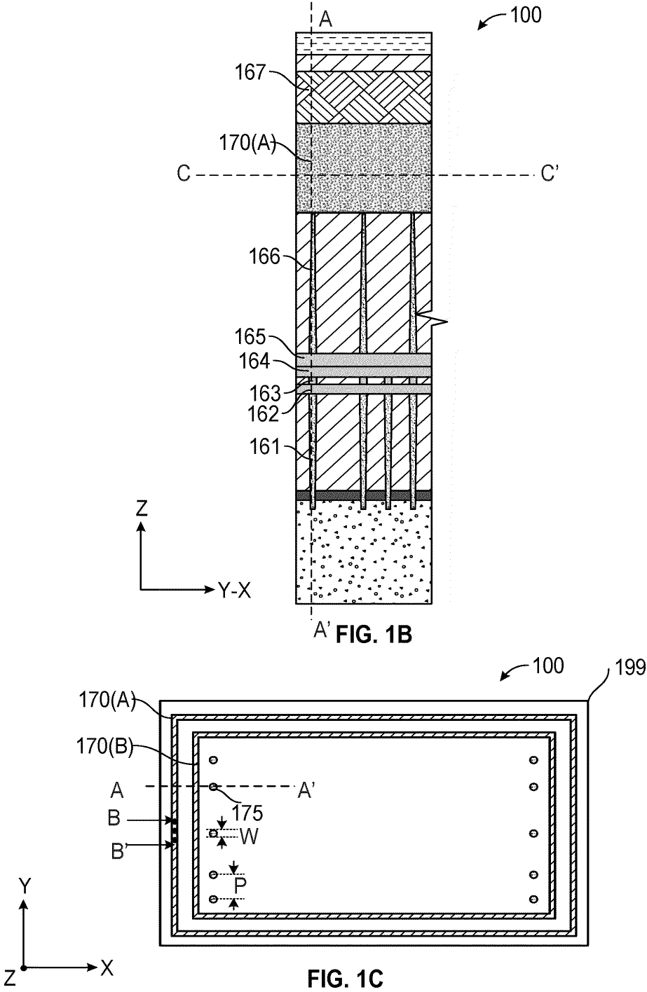

FIGS. 1A-1C shows cross-sectional views of a semiconductor device 100 according to some embodiments of the disclosure. FIG. 1A shows the cross-sectional view along A'A line of the semiconductor device 100 shown in FIG. 1B and FIG. 1C; FIG. 1B shows the cross-sectional view along B'B line of the semiconductor device 100 shown in FIG. 1A and FIG. 1C; and FIG. 1C shows the cross sectional view along C'C line of the semiconductor device 100 shown in FIG. 1A and FIG. 1B. It is noted that for ease of illustration, features are not drawn to scale.

The semiconductor device 100 includes multiple dies, such as a first die 101 and a second die 102 that are bonded face to face. The semiconductor device 100 includes passivation layers, such as a passivation layer 191, and the like protecting the back side of the first die 101 and the second die 102. Further, a seal ring structure 160 of metal material is formed in the semiconductor device 100 inside a side periphery 199 of the semiconductor device 100. The seal ring structure 160 includes a portion 170, such as shown by 170(A) and 170(B) in FIGS. 1A-1C, formed from a back side of one of the two dies, such as the back side of the first die 101, and the portion 170 extends through a semiconductor layer, such as silicon substrate 103, and the like. The semiconductor layer can be any suitable semiconductor layer. In following description, a silicon layer is used as an example of the semiconductor layer for ease of description. The silicon layer can be silicon substrate, epitaxy silicon layer and the like. The portion 170 in the silicon layer can be formed at the same time as through silicon contact (TSC) by the same process steps. TSC is also referred to as through silicon via (TSV) in some examples. The portion 170 is configured to have an elongated size along the side periphery 199 of the semiconductor device 100 compared to the through silicon contacts, and the portion 170 is referred to as through silicon wall (TSW) 170 in some examples. The seal ring structure 160 with the TSW 170 can improve reinforcement strength and improve protection for moisture and mobile ionic contaminants.

Specifically, as shown by the semiconductor device 100 in FIG. 1A, the first die 101 includes a memory cell array formed on the front side and can be referred to as an array die 101; and the second die 102 includes periphery circuitry formed on the front side and can be referred to as periphery die 102. In some examples, the periphery circuitry is formed using complementary metal-oxide-semiconductor (CMOS) technology, and the periphery die 102 is also referred to as CMOS die 102. It is noted that in another example (not shown), the first die 101 can be periphery die (or CMOS die) and the second die 102 can be array die.

It is noted that, in some other embodiments, a semiconductor device can include multiple array dies and a CMOS die. The multiple array dies and the CMOS die can be stacked and bonded together. The CMOS die is respectively coupled to the multiple array dies, and can drive the respective array dies to operate in the similar manner as the semiconductor device 100.

The semiconductor device 100 can be device at any suitable scale, such as wafer scale, chip scale, package scale and the like. In some examples (e.g., wafer scale), the semiconductor device 100 includes at least a first wafer and a second wafer bonded face to face. The array die 101 is disposed with other array dies on the first wafer, and the CMOS die 102 is disposed with other CMOS dies on the second wafer. The first wafer and the second wafer are bonded together, thus the array dies on the first wafer are bonded with corresponding CMOS dies on the second wafer. In some examples (e.g., chip scale), the semiconductor device 100 is a chip with at least the array die 101 and the CMOS die 102 bonded together. In an example, the chip is diced from wafers that are bonded together. In another example (e.g., package scale), the semiconductor device 100 is a semiconductor package that includes one or more semiconductor chips assembled on a package substrate.

In the FIGS. 1A-1C example, the array die 101 includes a substrate 103, and memory cells formed on the substrate 103. The CMOS die 102 includes a substrate 104, and peripheral circuitry formed on the substrate 104. For simplicity, the main surface of the substrate 103 is referred to as an X-Y plane, and the direction perpendicular to the main surface is referred to as Z direction.

The substrate 103 and the substrate 104 respectively can be any suitable substrate, such as a silicon (Si) substrate, a germanium (Ge) substrate, a silicon-germanium (SiGe) substrate, and/or a silicon-on-insulator (SOI) substrate. The substrate 103 and the substrate 104 respectively may include a semiconductor material, for example, a Group IV semiconductor, a Group III-V compound semiconductor, or a Group II-VI oxide semiconductor. The Group IV semiconductor may include Si, Ge, or SiGe. The substrate 103 and the substrate 104 respectively may be a bulk wafer or an epitaxial layer.

The semiconductor device 100 includes memory cell arrays and peripheral circuitry (e.g., the address decoding circuit, the page buffer circuit, the data I/O circuit, the voltage generator, the main controller and the like). In the FIG. 1A example, the memory cell arrays are formed on a front side of the substrate 103 of the array die 101 and the peripheral circuitry is formed on a front side of the substrate 104 of the CMOS die 102. The array die 101 and the CMOS die 102 are disposed face to face and bonded together. It is noted that generally, transistors are disposed on a front side (also referred to as first side, face side in some examples) of a substrate, the opposite side of the substrate is referred to as a back side (also referred to as second side in some examples), and the surface of the front side can be referred to as face.

According to an aspect of the disclosure, the seal ring structure 160 is formed inside the side periphery 199 of the bonded dies to protect regions inside the seal ring structure 166, and various circuit structures can be formed in the regions inside the seal ring structure 160.

In the FIGS. 1A-1C example, a block of three dimensional (3D) NAND memory cell strings can be formed on the array die 101. In some examples, the array die 101 includes staircase regions 106 and core regions 107 that are surrounded by the seal ring structure 160. The memory cells can be formed in the core region 106 as an array of vertical memory cell strings 105. In the FIG. 1A example, vertical memory cell strings 105 are shown as representation of an array of vertical memory cell strings formed in the core region 107.

The staircase region 106 (also referred to as a connection region in some examples) is used to facilitate making connections to, for example, gates of the memory cells in the vertical memory cell strings, gates of the select transistors, and the like. The gates of the memory cells in the vertical memory cell strings correspond to word lines in the NAND memory architecture. For example, a word line connection structure 150 includes a word line contact 151, and metal wire 152 that are conductively coupled together. The word line connection structure 150 can electrically couple a word line to a gate terminal of a transistor in a vertical memory cell string 105.

In the FIG. 1A example, the CMOS die 102 includes periphery circuity formed using CMOS technology. For example, the CMOS die 102 includes P-type doped wells 111 and N-type doped wells 110 formed in active areas (AAs, or referred to as active regions) of the substrate 104, the P-type doped wells 111 and the N-type doped wells 110 can be insulated by shallow trench isolation (STI) structures 113. P-type transistors can be formed in the N-type doped wells 110 and N-type transistors can be formed in the P-type doped wells 111.

The P-type transistors and the N-type transistors can be suitable coupled to form CMOS circuit. In some examples, the terminals of the N-type transistors and P-type transistors are coupled to patterned metal layers disposed on the front side of the CMOS die 102. FIG. 1A shows an N-type transistor 120 disposed in the P-type doped well 111. The N-type transistor 120 includes source/drain (S/D) terminals and a gate terminal (G), the S/D terminals and the G terminal are connected to a patterned metal layer that is referred to as M1 by some contact structures. For example, the S/D terminals are connected to M1 by contact structures C1 and C2, and the gate terminal is connected to M1 by a contact structure C3. The patterned metal layer M1 can be connected to other metal layers (e.g., M2, M3,...) disposed on the front side of the CMOS die 102 by via structures.

In the FIGS. 1A-1C example, the array die 101 and the CMOS die 102 are disposed face-to-face (circuitry side is face, and the substrate side is back) and bonded together. Generally, the periphery circuitry on the CMOS die 102 interfaces the semiconductor device 100 with external circuitry. For example, the periphery circuitry receives instructions from the external circuitry, provides control signals on the array die 101, receives data from the array die 101, and outputs data to the external circuitry.

In the FIG. 1A example, pad structures 137 are formed at the back side of the array die 101. The semiconductor device 100 includes I/O connection structures 130 to transmit I/O signals between the pad structures 137 and I/O circuitry on the CMOS die 102. An I/O connection structure 130 includes various portions, such as a bonding structure 134 formed on the CMOS die 102, a bonding structure 135 formed on the array die 101, a punch through contact structure 136 on the array die 101, a TSC 175 and the pad structure 137 on the array die 101. It is noted that the I/O connection structure 130 can include other portions, such as a via (not shown) between the bonding structure 135 and the punch through contact structure 136, a via 133 between the bonding structure 134 and a metal wire 132, the metal wire 132, and other vias (not shown) and metal wires (not shown) for routing between the bonding structure 134 and I/O circuitry on the CMOS die 102.

In an example, at a bonding time (e.g., to bond the first wafer including the array die 101 and the second wafer including the CMOS die 102 together), the bonding structure 134 on the CMOS die 102 and the bonding structure 135 on the array die 101 can be suitably aligned and bonded, thus the bonding structure 134 on the CMOS die 102 and the bonding structure 135 on the array die 101 are conductively connected.

According to some aspects of the disclosure, the seal ring structure 160 includes portions that are formed by process steps to form other structures in the semiconductor device 100. For examples, the seal ring structure 160 includes first portions formed from the front side of the CMOS die 102 by process steps to form structures on the front side of the CMOS die 102. The first portions include a bonding structure 164, a via structure 163, a metal wire 162, and a contact 161 in FIG. 1A example.

The seal ring structure 160 includes second portions formed by processing steps to form structures on the front side of the array die 101. The second portions include a bonding structure 165 and a punch through contact structure 166. It is noted that the second portions can include some parts that are not shown in FIGS. 1A-1C.

The seal ring structure 160 includes third portions formed from the back side of the array die 101. The third portions include the TSW 170 and a pad structure 167. It is noted that the third portions can include some parts that are not shown in FIGS. 1A-1C. It is noted that in the following description, TSW 170 is used as an example of techniques for forming metal walls as a portion of the seal ring structure 160, and the techniques for forming metal walls can be used in other portions of the seal ring structure 160, such as the punch through contact structure 166, the contact 161, the via structure 163 and the like. Further, techniques for forming metal walls in the seal ring structure using a contact (or via) metal layer can be used in any suitable semiconductor device, a single die device, a device of bonded dies, a memory array die, a CMOS die, and the like.

In some examples, the bonding structure 164 can be formed at the same time with other bonding structures, such as the bonding structure 134, by process steps to form bonding structures on the front side of the CMOS die 102; the via structure 163 can be formed at the same time with other via structures, such as the via 133, by process steps to form via structures on the front side of the CMOS die 102; the metal wire 162 can be formed at the same time with other metal wires, such as the metal wire 132, by process steps to form metal wires on the front side of the CMOS die 102.

In some examples, the bonding structure 165 can be formed at the same time with other bonding structures, such as the bonding structure 135, by process steps to form bonding structures on the front side of the array die 101; the punch through contact structure 166 can be formed at the same time with other punch through contact structures, such as the punch through contact structure 136, by process steps to form the punch through contact structures on the front side of the array die 101.

In some examples, the TSW 170 can be formed at the same time with TSCs, such as the TSC 175, by process steps to form TSCs at the back side of the array die 101; the pad structure 167 can be formed at the same time with pad structures, such as the pad structure 137, by process steps to form pad structures at the back side of the array die 101.

Generally, portions of the seal ring structure 160 that are formed with patterned metal layers, such as metal wires, pad structures, bonding structures, and the like can be formed with elongated length along the side periphery 199, for example, in the form of metal walls in a loop shape, such as a closed loop, a loop with gaps, and the like. Further, portions of the seal ring structure 160 that are formed with contacts or vias are formed as metal poles in some related examples.

According to some aspects of the disclosure, the TSW 170 that is formed with the TSC 175 is configured to include metal wall(s). The metal wall(s) in the TSW 170 can provide improved reinforcement strength and improved protection for moisture and mobile ionic contaminants than metal poles used in the related examples.

As shown in FIG. 1B and FIG. 1C, the TSW 170 in the seal ring structure 160 that is formed with the TSC 175 can be formed in the form of a metal wall, while the TSC 175 is formed in the form of a metal pole. The TSC 175 has about the same width in X direction and Y direction in the X-Y plane as shown in FIG. 1C, and the metal wall has an elongated length along the side periphery 199 compared to TSC 175 as shown in FIG. 1C. It is noted that a cross-sectional view of the the TSC 175 in a direction parallel to the B'B line is about the same as shown in FIG. 1A.

In an example, the length of the TSW 170 along the side periphery is longer than a width (W) of the TSC 175. In another example, the length of the TSW 170 along the side periphery is longer than a pitch (P) of the TSC 175 (e.g., a sum of a width of a TSC and a minimum space between adjacent TSCs). Due to the reason that the TSW 170 has elongated length along the side periphery direction, the TSW 170 can provide larger reinforcement strength than metal poles (e.g., the TSC 175). Further, because the TSW 170 can cover larger area along the side peripheral than metal poles (e.g., the TSC 175), the TSW 170 can provide better protection for moisture and mobile ionic contaminants than the related examples that use only metal poles.

According to an aspect of the disclosure, the TSW 170 can be formed in a closed loop that encloses regions of circuitry structures. As shown in FIG. 1C, the seal ring structure 160 includes the TSW 170(A) and TSW 170(B). The TSW 170(A) is an outer loop and the TSW 170(B) is an inter loop. Both loops are closed loops.

It is noted that the TSWs 170 can have other suitable loop patterns.

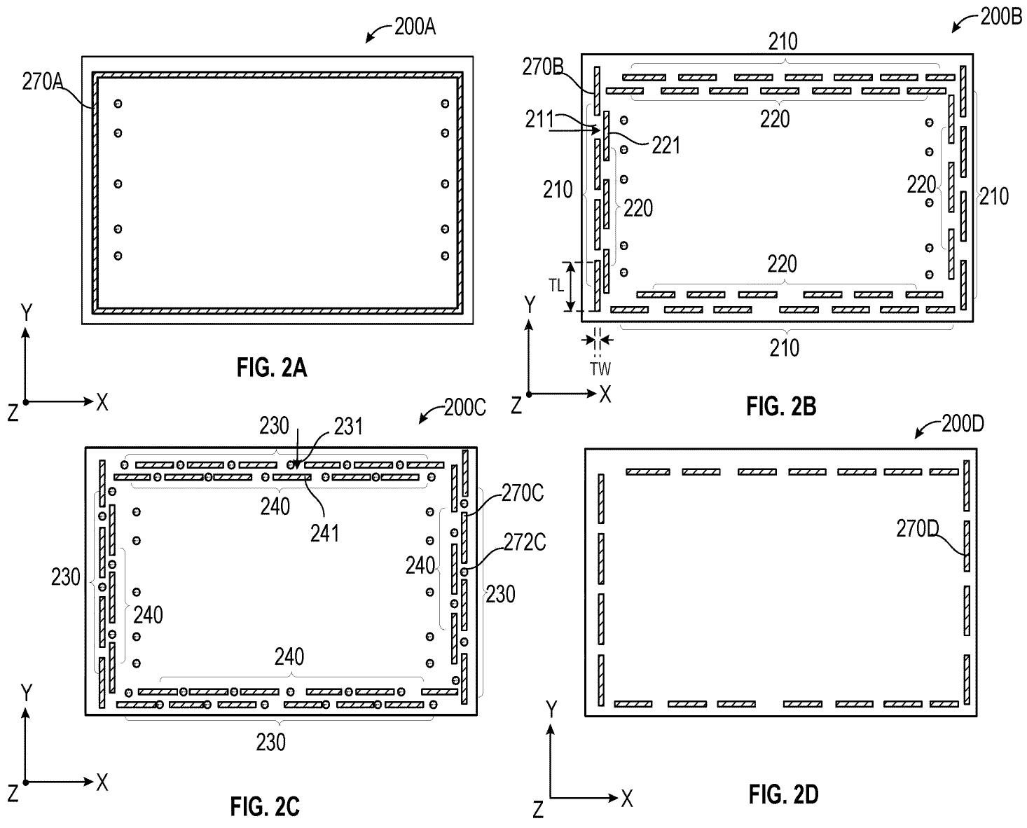

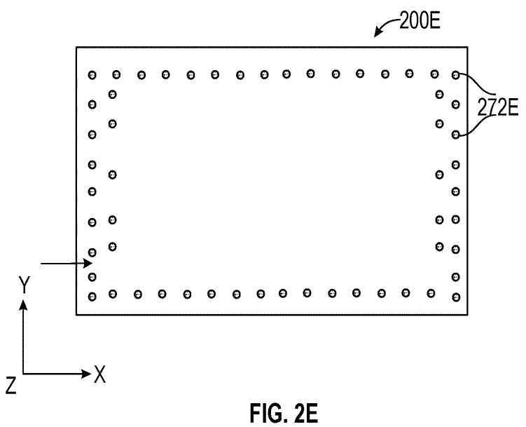

FIGS. 2A-2D show the cross sectional views of some other semiconductor device along a similar line as C'C line in the example of FIGS. 1A-1C. FIG. 2E shows a cross section view of a related semiconductor device a long a similar line as C'C line.

FIG. 2A shows a cross sectional view of a semiconductor device 200A according to some embodiments of the disclosure. A seal ring structure formed inside a side periphery of the semiconductor device 200A includes a TSW 270A that is configured to be a single closed loop.

FIG. 2B shows a cross sectional view of a semiconductor device 200B according to some embodiments of the disclosure. A seal ring structure formed inside a side periphery of the semiconductor device 200B includes multiple TSWs 270B that form multiple loops along the side the periphery. Each loop includes multiple TSWs 270B and includes gaps between adjacent TSWs. In some examples, TSWs in different loops are staggered, and thus a gap in one of the loops is blocked by TSWs in other loops. In the FIG. 2B example, multiple TSW 270B form an outer loop 210 and an inner loop 220. The outer loop 210 includes multiple TSWs 270B and gaps between the adjacent TSWs. The inner loop 220 includes multiple TSWs 270B and gaps between the adjacent TSWs. Gaps in the outer loop 210 are blocked by TSWs in the inner loop 220; and gaps in the inner loop 220 are blocked by TSWs in the outer loop 210. For example, a gap 211 in an outer loop 210 is in the Y direction between two TSWs, and a penetration path (show by arrow) in X direction through the gap 211 is blocked by TSW 221 in the inner loop 220. In some examples, the width (TW) of each of TSW 270B is about the same as the width of TSCs (e.g., the width W shown in FIG. 1C), and the length (TL) of each TSW 270B along the side periphery is longer than the pitch of the TSCs (e.g., the pitch P shown in FIG. 1C).

FIG. 2C shows a cross sectional view of a semiconductor device 200C according to some embodiments of the disclosure. A seal ring structure formed inside a side periphery of the semiconductor device 200C includes multiple TSWs 270C and multiple TSCs 272C that form multiple loops along the side the periphery. Each loop includes multiple TSWs 270C and multiple TSCs 272C, and includes gaps between adjacent TSWs/TSCs. In some examples, TSWs in different loops are staggered, and thus a gap in one of the loops is blocked by TSWs in other loops. In the FIG. 2C example, the multiple TSWs 270C and multiple TSCs 272C form an outer loop 230 and an inner loop 240. The outer loop 230 includes multiple TSWs 270C and multiple TSCs 272C and gaps between the adjacent TSW 270C and TSC 272C. The inner loop 220 includes multiple TSWs 270C and multiple TSCs 272C and gaps between the adjacent TSW 270C and TSC 272C. Gaps in the outer loop 230 are blocked by TSWs in the inner loop 240; and gaps in the inner loop 240 are blocked by TSWs in the outer loop 230. For example, a gap 231 in an outer loop 230 is in the X direction between a TSW and a TSC, and a penetration path (show by arrow) in Y direction through the gap 231 is blocked by TSW 241 in the inner loop 240. In some examples, the width of each of TSW 270C is about the same as the width of TSC 272C, and the length of each TSW 270C along the side periphery is longer than the pitch of the TSCs (e.g., the pitch P shown in FIG. 1C).

FIG. 2D shows a cross sectional view of a semiconductor device 200D according to some embodiments of the disclosure. A seal ring structure formed inside a side periphery of the semiconductor device 200D includes multiple TSWs 270D that form a single loop along the side the periphery. The single loop includes multiple TSWs 270D and includes gaps between adjacent TSWs. In some example, the width (TW) of each of TSW 270D is about the same as the width of TSCs (e.g., the width W shown in FIG. 1C), and the length (TL) of each TSW 270D along the side periphery is longer than the pitch of the TSCs (e.g., the pitch P shown in FIG. 1C).

FIG. 2E shows a cross sectional view of a related semiconductor device 200E. A seal ring structure of the related semiconductor device includes solely TSCs 272E. The gaps between adjacent TSCs 272E can provide a path (e.g., shown by an arrow line) for moisture and mobile ionic contaminants to enter functional circuit area of the related semiconductor device.

Comparing FIG. 2D with FIG. 2E, the TSWs 270D can cover a longer portion of the side periphery than the TSCs 272E. Thus, the TSWs 270D can provide better protection against moisture and mobile ionic contaminants than the TSCs 272E.

According to another aspect of the disclosure, the punch through contact structure 166 in the seal ring structure 160 can be replaced by metal wall to provide improved reinforcement strength and improved protection for moisture and mobile ionic contaminants.

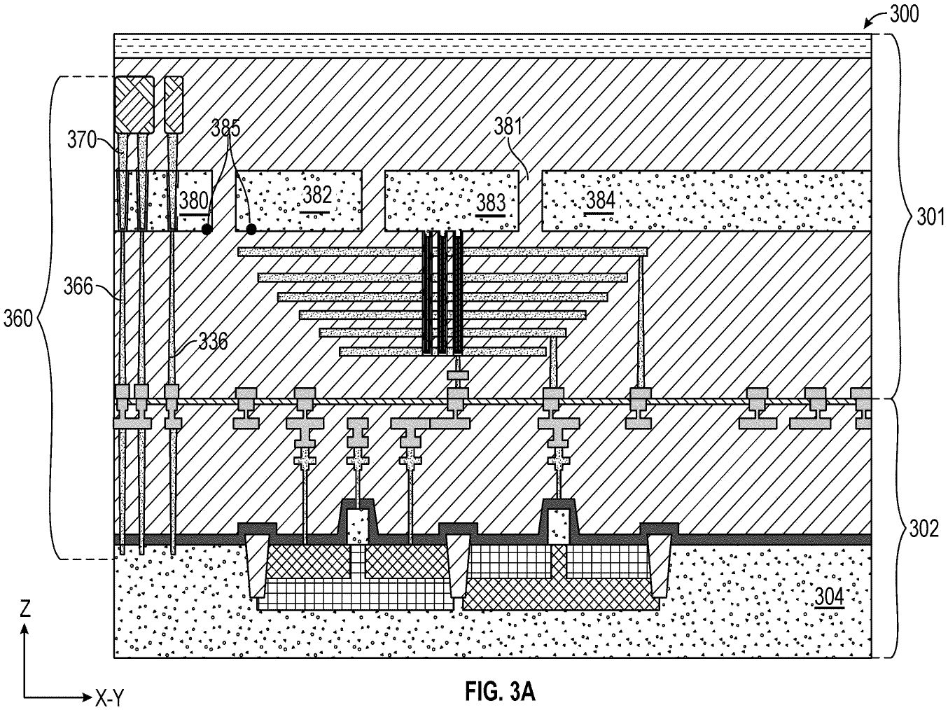

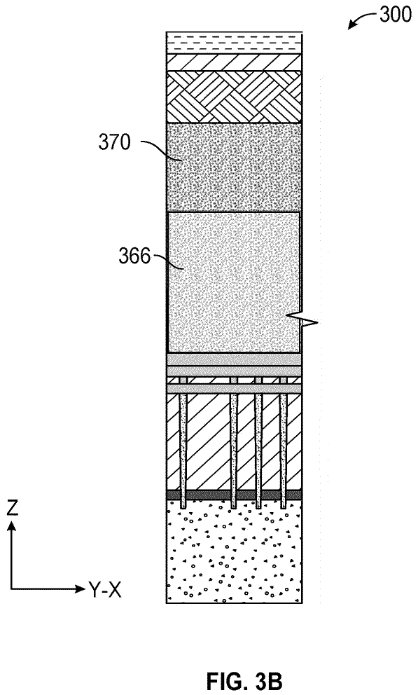

FIGS. 3A-3B shows cross-sectional views of a semiconductor device 300 according to some embodiments of the disclosure. FIG. 3A shows the cross-sectional view similar to the cross-sectional view in FIG. 1A, and FIG. 3B shows the cross-sectional view similar to the cross-sectional view in FIG. 1B.

The semiconductor device 300 includes components that are identical or equivalent to those used in the semiconductor device 100 described above. For example, the semiconductor device 300 includes a first die 301 and a second die 302 bonded face to face. The description of these components has been provided above and will be omitted here for clarity purposes. However, in the FIGS. 3A-3B example, the substrate of the first die 301 has been removed, and additional layers, such as a semiconductor layer 380, and insulating portions 381 are formed at the back side of the first die 301. In some examples, functional circuitry, such as a portion of periphery circuitry of the 3D NAND memory array, can be formed in some portions 382-384 of the semiconductor layer 380. In some embodiments, defects 385, such as cracks and the like can be formed at the interface of the additional layers to existing portions. The defects 385 may provide paths for moisture and mobile ionic contaminants to go up or down and into active circuitry regions.

According to an aspect of the disclosure, the seal ring structure 360 of metal material is formed in the semiconductor device 300 inside a side periphery of the semiconductor device 300. The seal ring structure 360 includes a portion 370 that is formed similarly as the portion 170 in FIG. 1A. Additionally, the seal ring structure 360 includes a portion 366, formed from the front side of the first die 101. The portion 366 is formed in the form of a metal wall instead of a metal pole. In some examples, the portion 366 is formed with punch through contact structures 336 by the same process steps that operate on the front side of the first die 301 to form the punch through contact structures 336. The portion 366 is referred to as punch through wall 366 in some examples.

According to some aspects of the disclosure, the punch through wall 366 that is formed with punch through contact structures 336 is configured to include metal wall(s). The metal wall(s) in the punch through wall 366 can provide improved reinforcement strength and improved protection for moisture and mobile ionic contaminants than metal poles. In some examples, the punch through contact structures 336 has about the width in the X direction and the Y direction in X-Y plane, and the metal wall in the punch through wall 366 has an elongated length along the side periphery compared to the punch through contact structures 336.

It is noted that the punch through wall 366 can be configured to have any suitable patterns in the X-Y plane, such as patterns similar to the TSW 170 in FIG. 1C, the TSW 270A in FIG. 2A, the TSW 270B in FIG. 2B and the TSW 270C in FIG. 2C.

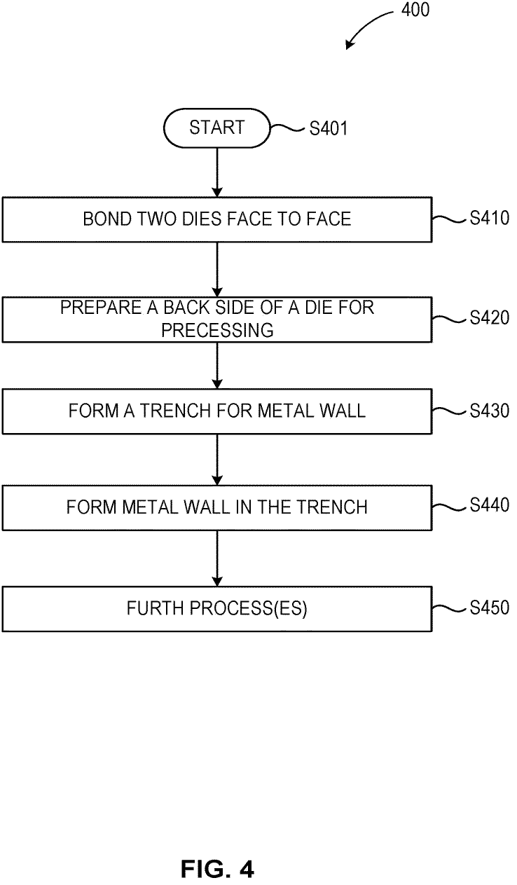

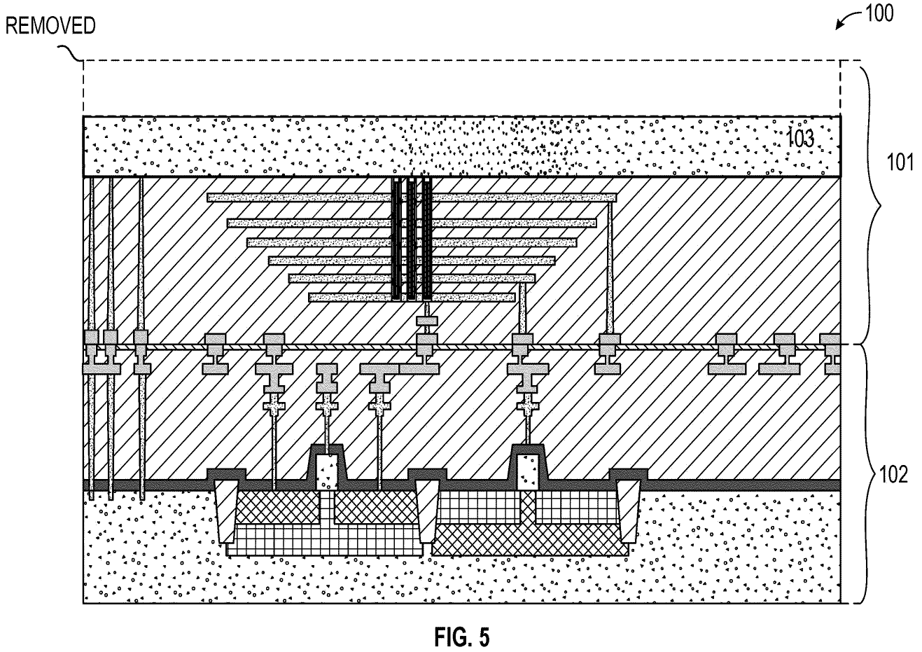

FIG. 4 shows a flow chart outlining a process 400 for forming a semiconductor device, such as the semiconductor device 100 according to some embodiments of the disclosure, and FIGS. 5-7 show cross-sectional views of the semiconductor device 100 during the process in accordance with some embodiments. The process 400 starts from S401 and proceeds to S410.

At S410, two dies are bonded face to face. In some embodiments, the array die 101 is fabricated with other array dies on a first wafer and the CMOS die 102 is fabricated with other CMOS dies on a second wafer. In some examples, the first wafer and the second wafer are fabricated separately.

In some examples, memory cell arrays are formed on the first wafer using processes that operate on the face side of the first wafer, and bonding structures are formed on the face side of the first wafer.

Similarly, periphery circuitry is formed on the second wafer using CMOS processes that operate on the face side of the second wafer, and bonding structures are formed on the face side of the second wafer.

In some embodiments, the first wafer and the second wafer can be bonded face to face using a wafer-to-wafer bonding technology. The bonding structures on the first wafer are bonded with corresponding bonding structures on the second wafer, thus the CMOS dies on the second wafer are respectively bonded with the array dies on the first wafer.

At S420, a back side of the one of the two dies, such as the array die 101, is prepared for further processing.

In some examples, the CMOS die 102 and the array die 101 are bonded face to face and then the array die 101 is thinned from the back side of the array die 101.

FIG. 5 shows a cross-sectional view of the semiconductor device 100 after a portion of the substrate 103 is removed from the back side by a thinning process. The semiconductor device 100 includes the array die 101 and the CMOS die 102 that are bonded face to face. Then, the substrate 103 is thinned from the back side to remove a portion of the substrate 103 as shown by “REMOVED” in FIG. 5.

In some examples, after a wafer-to-wafer bonding process, the first wafer is thinned from the back side of the first wafer. In an example, a chemical mechanical polishing (CMP) process or a grind process is used to remove a portion of the bulk silicon from the back side of the first wafer.

In some other examples, the substrate 103 are completely removed, and additional layers, such as silicon layer 380 and insulating layer 381 in FIG. 3A can be formed on the back side of the first wafer.

Referring back to FIG. 4, at S430, a trench in a semiconductor layer is generated by processing on the back side of the die. The trench will be used for forming a metal wall. In some embodiments, the trench is generated with the generation of holes for TSCs.

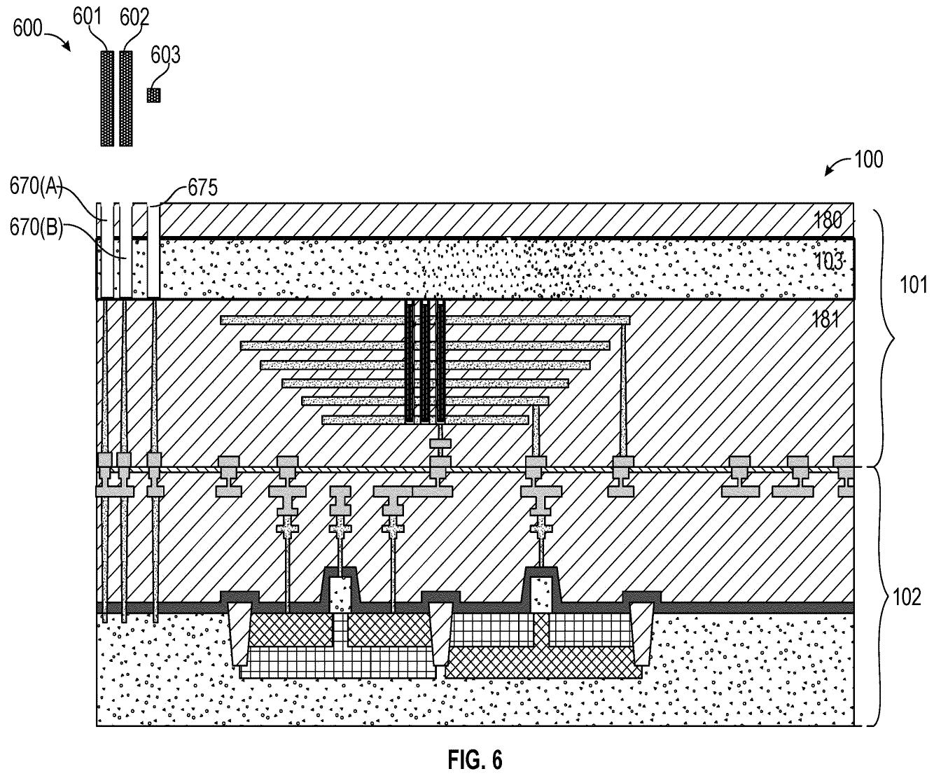

FIG. 6 shows a cross-sectional view of the semiconductor device 100 after trenches 670(A) and 670(B) for forming metal walls are generated in the substrate 103. In some examples, an insulating layer 180 is deposited on the backside of the substrate 103, and a mask 600 is used to define the trenches 670(A) and 670(B) in the insulating layer 180 and the substrate 103. The mask 600 can be generated according to a layout design. The layout design includes a layout layer for forming TSW and TSCs. The layout layers can includes patterns corresponding to the TSW and TSC patterns in FIG. 1C, FIG. 2A, FIG. 2B and FIG. 2C. In the FIG. 6 example, the mask 600 includes various patterns, such as a first pattern 601, a second patterns 602, a third pattern 603 and the like. The first pattern 601 and the second pattern 602 correspond to the metal walls and can be transferred by an etch process into the insulating layer 180 and the substrate 103 as the trenches 670(A) and 670(B) that stop at an interface to an insulating layer 181 disposed on the front side of the silicon substrate 103. The third pattern 603 correspond to a TSC and the third pattern 603 can be transferred by the etch process into the insulating layer 180 and the substrate 103 as a hole 675 that stop at the interface to the insulating layer 181.

It is noted that a layout can be suitably designed and corresponding mask can be generated and used similarly as the mask 600.

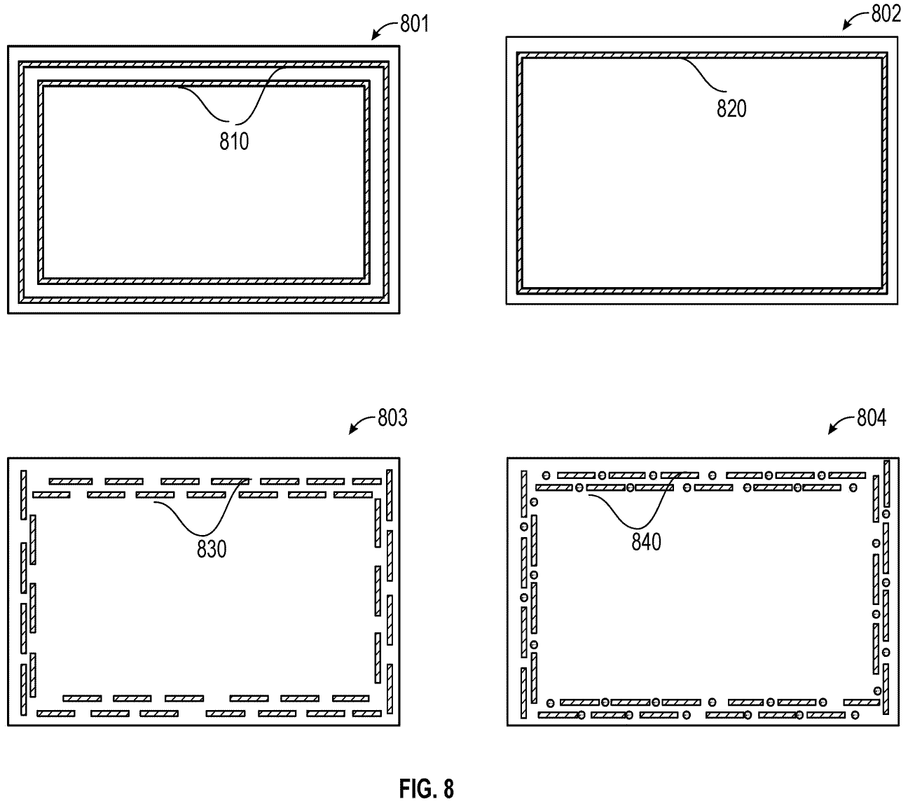

FIG. 8 shows layout designs 801, 802, 803 and 804. In an example, the layout design 801 includes patterns 810 for TSWs. According to the patterns 810, TSWs 170(A) and 170(B) can be formed. In another example, the layout design 802 includes patterns 820 for TSWs. According to the patterns 820, TSW 270A can be formed. In another example, the layout design 803 includes patterns 830 for TSWs. According to the patterns 830, TSW 270B can be formed. In another example, the layout design 804 includes patterns 840 for TSWs. According to the patterns 840, TSW 270C can be formed.

It is noted that the patterns 810 have the equivalent dimension and placement properties as the TSWs 170(A) and 170(B); the patterns 820 have the equivalent dimension and placement properties as the TSWs 270A; the patterns 830 have the equivalent dimension and placement properties as the TSWs 270B; and the patterns 840 have the equivalent dimension and placement properties as the TSWs 270C. The description of the dimension and placement properties has been provided above and will be omitted here for clarity purposes.

Referring back to FIG. 4, at S440, a metal wall is formed in the trench.

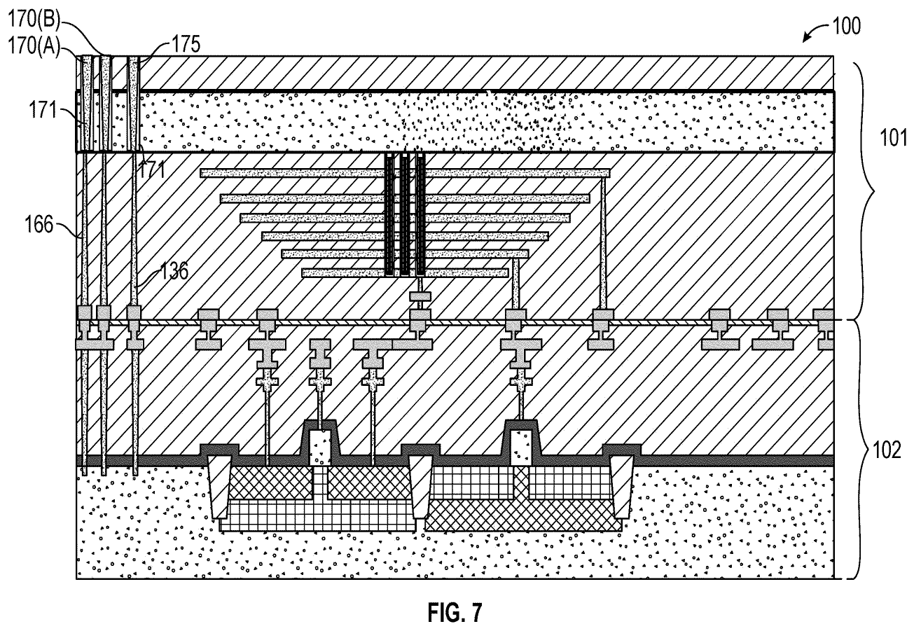

FIG. 7 shows a cross-sectional view of the semiconductor device 100 after the metal walls 170(A) and (170B) are formed in the trenches 670(A) and 670(B). In some examples, an insulating layer 171 is deposited on the back side of the array die 101. In some embodiments, the insulating layer 171 is deposited using a deposition technology that generates a conformal thin film layer. For example, atomic layer deposition (ALD) can be used to form the insulating layer 171. For the hole 675 and the trenches 670(A) and 670(B), the insulating layer 171 is deposited on the side walls and bottom.

In some examples, after the deposition of the insulating layer 171, an etch process can be performed to remove the insulating layer 171 at the bottom of the hole 675 and the bottom of the trenches 670(A) and 670(B). The removal of the insulating layer 171 at the bottom of the hole 675 and the bottom of the trenches 670(A) and 670(B) reveals the ends of punch through contact structures 166 and 136.

Then, a metal layer is filled into the trenches 670(A) and 670(B) and the hole 657. In the hole 675, the filled metal layer is in contact with the end of punch through contact structure 136 and forms the TSC 175. In the trenches 670(A) and 670(B), the filled metal layer forms the metal walls of the TSWs 170(A) and 170(B).

In some examples, tungsten is deposited to fill the trenches 670(A) and 670(B) and the hole 657 and the portion of the tungsten on the surface of the insulating layer 180 can be removed by CMP process.

Referring back to FIG. 4, at S450, additional processes can be further performed. For example, a back side metal layer can be formed and patterned. The patterned metal layer can form routing paths and pad structures. In some examples, the bonded wafers can be sawed into chips, each chip includes an array die and a CMOS die bonded together. According to an aspect of the disclosure, the metal walls, such as the TSWs 170(A) and 170(B) can provide improved reinforcement strength for further processing on the back side of the array die, and can provide improved protection for moisture and mobile ionic contaminants.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first die comprising:
a silicon layer;
first circuit structures formed in a region of the silicon layer; and
a seal ring structure surrounding the region, the seal ring structure comprising a first wall structure extending through the silicon layer, a first length of the first wall structure along a side periphery of the first die being longer than a pitch of contact structures.

2. The semiconductor device of claim 1, wherein the first wall structure is formed by a metal material.

3. The semiconductor device of claim 1, wherein the first wall structure through the silicon layer is configured to be a closed loop that encloses the region.

4. The semiconductor device of claim 1, wherein the first die comprises multiple first wall structures that extend through the silicon layer, the multiple first wall structures form a first loop along the side periphery of the first die, the first loop encloses the region and includes gaps between adjacent first wall structures.

5. The semiconductor device of claim 4, wherein the first die comprises multiple second wall structures that extend through the silicon layer, the multiple second wall structures form a second loop along the side periphery of the first die, the second loop encloses the multiple first wall structures and the region, the multiple first wall structures and the multiple second wall structures are staggered.

6. The semiconductor device of claim 5, wherein a gap between two of the multiple second wall structures is blocked by one of the multiple first wall structures.

7. The semiconductor device of claim 1, wherein the first die comprises:
an insulating layer; and
a third wall structure that extends through the insulating layer.

8. The semiconductor device of claim 1, wherein the first circuit structures are formed on a face side of the first die, and the semiconductor device further comprises:
a second die that is bonded face-to-face with the first die, the second die comprising:
second circuit structures formed on a face side of the second die.

9. The semiconductor device of claim 8, wherein the first circuit structures include an NAND memory array, and the second circuit structures include periphery circuitry for the NAND memory array.

10. A method for semiconductor device fabrication, comprising:
forming first circuit structures in a region of a first die; and
forming a seal ring structure surrounding the region, the seal ring structure comprising a first wall structure that extends through a silicon layer of the first die, a first length of the first wall structure along a side periphery of the first die being longer than a pitch of contact structures.

11. The method of claim 10, wherein forming the seal ring structure surrounding the region further comprises:
forming the first wall structure and first contact structures that extend through the silicon layer with a metal material, the first length of the first wall structure along the side periphery of the first die being longer than a pitch of the first contact structures.

12. The method of claim 11, wherein forming the first wall structure and the first contact structures further comprises:
forming a trench and holes in the silicon layer; and
filling the metal material in the trench and the holes to form the first wall structures in the trench and the first contact structures in the holes.

13. The method of claim 10, wherein forming the seal ring structure surrounding the region further comprises:
forming the first wall structure as a closed loop that encloses the region.

14. The method of claim 10, wherein forming the seal ring structure surrounding the region further comprises:
forming first wall structures in a first loop along the side periphery of the first die, the first loop enclosing the region and including gaps between adjacent first walls structures.

15. The method of claim 14, further comprising
forming second wall structures in a second loop along the side periphery of the first die, the second loop enclosing the first wall structure and the region, the first wall structures and the second wall structures being staggered.

16. The method of claim 14, further comprising
forming second wall structures in a second loop along the side periphery of the first die, the second loop enclosing the first wall structure and the region, a gap between two of the second wall structures being blocked by one of the first wall structures.

17. The method of claim 10, further comprising:
bonding the first die with a second die face to face; and
forming the first wall structure by processing from a back side of the first die.

18. The method of claim 17, wherein forming the first wall structure by processing from the back side of the first die further comprises:
thinning a silicon substrate of the first die from the back side of the first die; and
forming the first wall structure in the thinned silicon substrate.

19. The method of claim 17, wherein forming the first metal wall by processing from the back side of the first die further comprises:
removing a silicon substrate from the back side of the first die;
depositing the silicon layer at the back side of the first die; and
forming the first wall structure in the silicon layer.

20. The method of claim 10, further comprising:
forming a third wall structure that extends through an insulating layer.
